(19) United States
(12) Patent Application Publication
(10) Pub. No.: US 2026/0096287 A1
(43) Pub. Date: Apr. 2, 2026

(54) ORGANIC LIGHT EMITTING ELEMENT AND MANUFACTURING METHOD THEREOF

(71) Applicant: TAIZHOU GUANYU TECHNOLOGY CO., LTD., ZHEJIANG PROVINCE (CN)

(72) Inventors: RENHUI RUAN, ZHEJIANG PROVINCE (CN); HUEI-SIOU CHEN, TAIPEI CITY (TW)

(21) Appl. No.: 19/312,330

(22) Filed: Aug. 28, 2025

(30) Foreign Application Priority Data
Sep. 30, 2024 (CN) 202411378525.9

(51) Int. Cl. H10K 50/844; H10K 50/805; H10K 71/00; H10K 71/20; H10K 102/00

(52) U.S. Cl. CPC H10K 50/844; H10K 50/805; H10K 71/233; H10K 71/621; H10K 2102/351

(57) ABSTRACT

An organic light emitting element includes a substrate, a first bottom electrode, a first organic light emitting layer, a second organic light emitting layer, a first top electrode, a second top electrode, a first cover layer and a second cover layer. The first and second organic light emitting layers are located over the first bottom electrode. The first and second top electrodes are respectively located over the first and second organic light emitting layers, and an extension direction of the first top electrode and an extension direction of the second top electrode are substantially perpendicular to an extension direction of the first bottom electrode. The first and second cover layers are respectively located over the first and second top electrodes, and the first cover layer and the second cover layer are separated from each other.

### FIELD OF THE PRESENT DISCLOSURE

The present disclosure relates to an organic light emitting element and a manufacturing method thereof, and more particularly to an organic light emitting element including an organic light emitting diode (OLED) structure and a manufacturing method thereof.

### DESCRIPTION OF THE PRIOR ART

Currently, a fine metal mask (FMM) is commonly used in a coating step for a light emitting layer of an organic light emitting element, or a white light in combination with a color film are used for a manufacturing process. However, fineness or resolution of pixels resulted from the manufacturing processes above is rather poor.

### SUMMARY OF THE PRESENT DISCLOSURE

In the present disclosure, an organic light emitting element includes a substrate, a first bottom electrode, a first organic light emitting layer, a second organic light emitting layer, a first top electrode, a second top electrode, a first cover layer and a second cover layer. The first organic light emitting layer and the second organic light emitting layer are located over the first bottom electrode. The first top electrode and the second top electrode are respectively located over the first organic light emitting layer and the second organic light emitting layer, and an extension direction of the first top electrode and an extension direction of the second top electrode are substantially perpendicular to an extension direction of the first bottom electrode. The first cover layer and the second cover layer are respectively located over the first top electrode and the second top electrode, and the first cover layer and the second cover layer are separated from each other.

In the present disclosure, a manufacturing method of an organic light emitting element includes: providing a substrate; arranging a first bottom electrode over the substrate; forming an organic light emitting layer structure over the first bottom electrode; forming a top electrode material layer over the organic light emitting layer structure; forming a cover material layer over the top electrode material layer; and performing a separation step to separate the cover material layer into a first cover layer and a second cover layer separated from each other.

In some embodiments, the organic light emitting element further includes a top encapsulation layer, which continuously extends over the first cover layer and the second cover layer.

In some embodiments, the organic light emitting element further includes an insulation protrusion located over the substrate and partially covering the first bottom electrode, wherein a portion of the top encapsulation layer extends to between the first cover layer and the second cover layer and is in contact with the insulation protrusion.

In some embodiments, the first organic light emitting layer and the second organic light emitting layer are in contact with the top encapsulation layer and are separated from each other by the top encapsulation layer.

In some embodiments, the first cover layer and the second cover layer are separated from each other by the top encapsulation layer.

In some embodiments, the first cover layer includes a first capping layer and a first encapsulation layer located over the first capping layer, the second cover layer includes a second capping layer and a second encapsulation layer located over the second capping layer, and the first encapsulation layer and the second encapsulation layer are in contact with the top encapsulation layer and are separated from each other by the top encapsulation layer.

In some embodiments, the first top electrode and the second top electrode are in contact with the top encapsulation layer and are separated from each other by the top encapsulation layer.

In some embodiments, the organic light emitting element further includes an insulation protrusion located over the substrate and partially covering the first bottom electrode, wherein the first cover layer and the second cover layer are separated from each other by a space and a portion of the insulation protrusion is exposed from the space.

In some embodiments, the insulation protrusion includes a trench, and the trench is in communication with the space.

In some embodiments, the organic light emitting element further includes a top encapsulation layer, which continuously extends over the first cover layer and the second cover layer and extends into the space and the trench.

In some embodiments, a sidewall of the trench is recessed relative to a sidewall of the first organic light emitting layer.

In some embodiments, a sidewall of the first organic light emitting layer is recessed relative to a sidewall of the trench.

In some embodiments, a sidewall of the first organic light emitting layer is recessed relative to a sidewall of the first cover layer.

In some embodiments, a sidewall of the first organic light emitting layer is recessed relative to a sidewall of the first top electrode.

In some embodiments, the manufacturing method of an organic light emitting element further includes forming a top encapsulation layer continuously extending over the first cover layer and the second cover layer.

In some embodiments, the manufacturing method of an organic light emitting element further includes, before the forming of the top encapsulation layer, performing a separation step to separate a top electrode material layer into the first top electrode and the second top electrode separated from each other.

In some embodiments, the manufacturing method of an organic light emitting element further includes, before the forming of the top encapsulation layer, performing a separation step to separate an organic light emitting layer structure into the first organic light emitting layer and the second organic light emitting layer separated from each other.

In some embodiments, the manufacturing method of an organic light emitting element further includes, before the performing of a separation step, arranging a patterned photosensitive layer over a cover material layer; and after the performing of a separation step, removing the patterned photosensitive layer by a wet etching step, wherein the wet etching step further removes a portion of the first organic light emitting layer and a portion of the second organic light emitting layer, such that a sidewall of the first organic light emitting layer and a sidewall of the second organic light emitting layer are recessed relative to a sidewall of the first cover layer.

In some embodiments, the manufacturing method of the organic light emitting element further includes forming an insulation protrusion over the substrate to partially cover the first bottom electrode, wherein the separation step further removes a portion of the insulation protrusion.

### BRIEF DESCRIPTION OF THE DRAWINGS

FIG. 1 is a top view of an exemplary intermediate product of an organic light emitting element.

FIG. 2A is a section diagram of an organic light emitting element.

FIG. 2B is a section diagram of an organic light emitting element.

FIG. 2C is a section diagram of an organic light emitting element.

FIG. 2D is a section diagram of an organic light emitting element.

FIG. 2E is a section diagram of an organic light emitting element.

FIG. 3A to FIG. 3E depict a manufacturing method of an organic light emitting element according to some embodiments.

### DETAILED DESCRIPTION OF THE EMBODIMENTS

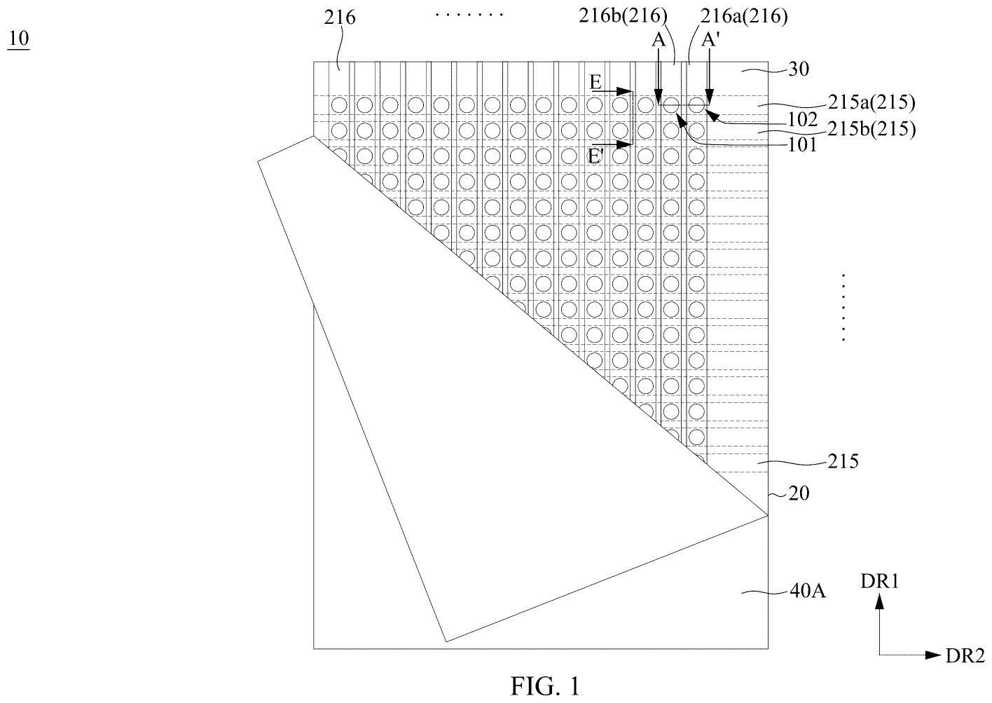

FIG. 1 shows a top view of an exemplary intermediate product of an organic light emitting element 10. The organic light emitting element 10 may include a light emitting layer 20 and a cover structure 40A located over the light emitting layer 20. For the light emitting layer 20, a spacer structure 30 may be designed to provide a recess array used to accommodate a light emitting pixel array. In some embodiments, the spacer structure 30 serves as a pixel defined layer (PDL). In some embodiments, the spacer structure 30 may include a protrusion 310. In some embodiments, the protrusion 310 defines a pixel region. In some embodiments, the spacer structure 30 may include a photosensitive material.

As shown in FIG. 1, the organic light emitting element 10 may further include an electrode 215 (or referred to as a bottom electrode) and an electrode 216 (or referred to as a top electrode). In some embodiments, the electrode 215 is an anode and the electrode 216 is a cathode. In some embodiments, the organic light emitting element 10 may include multiple electrodes 215 and multiple electrodes 216, for example, electrodes 215a and 215b, and electrodes 216a and 216b. In some embodiments, an extension direction DR2 of the electrode 215 is substantially perpendicular to an extension direction DR1 of the electrode 216.

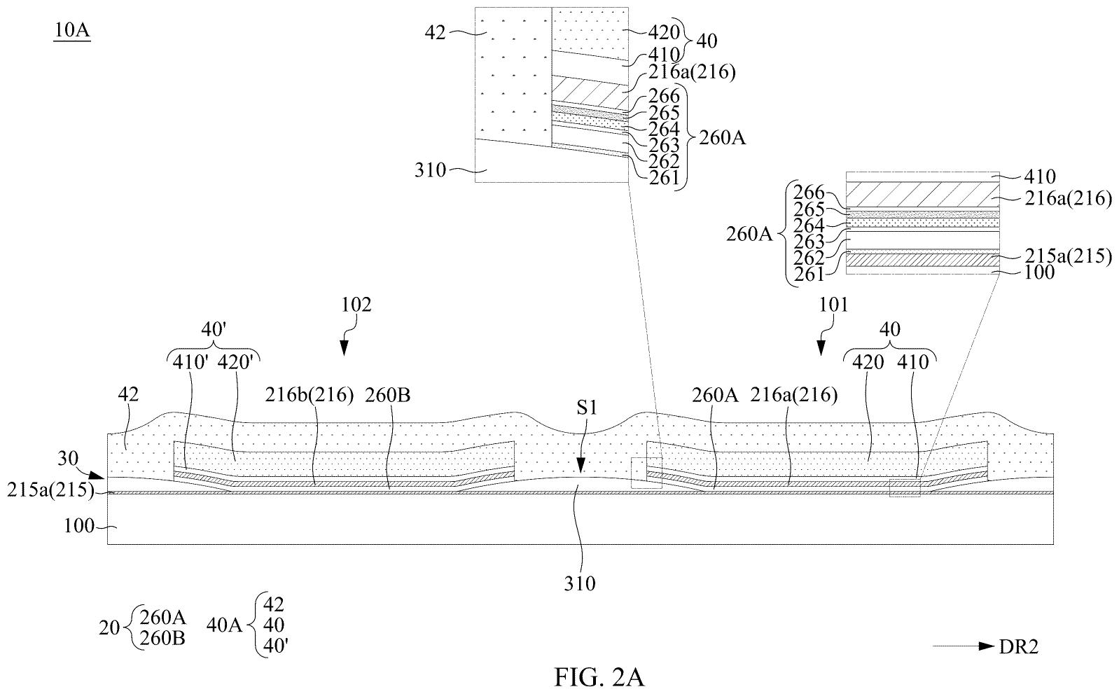

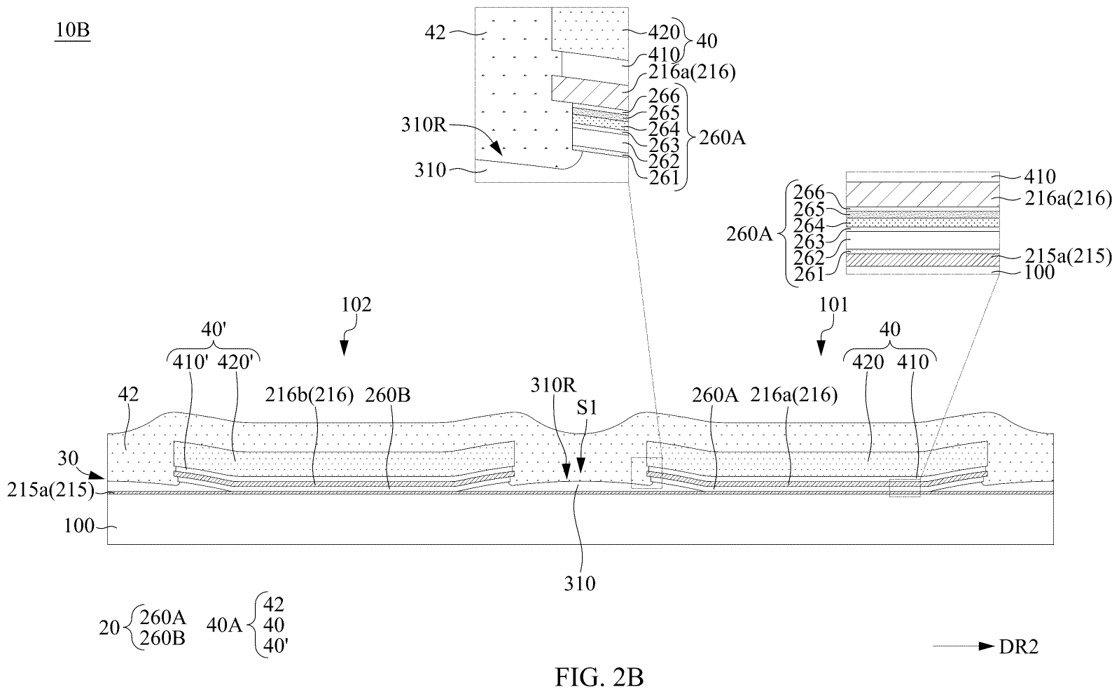

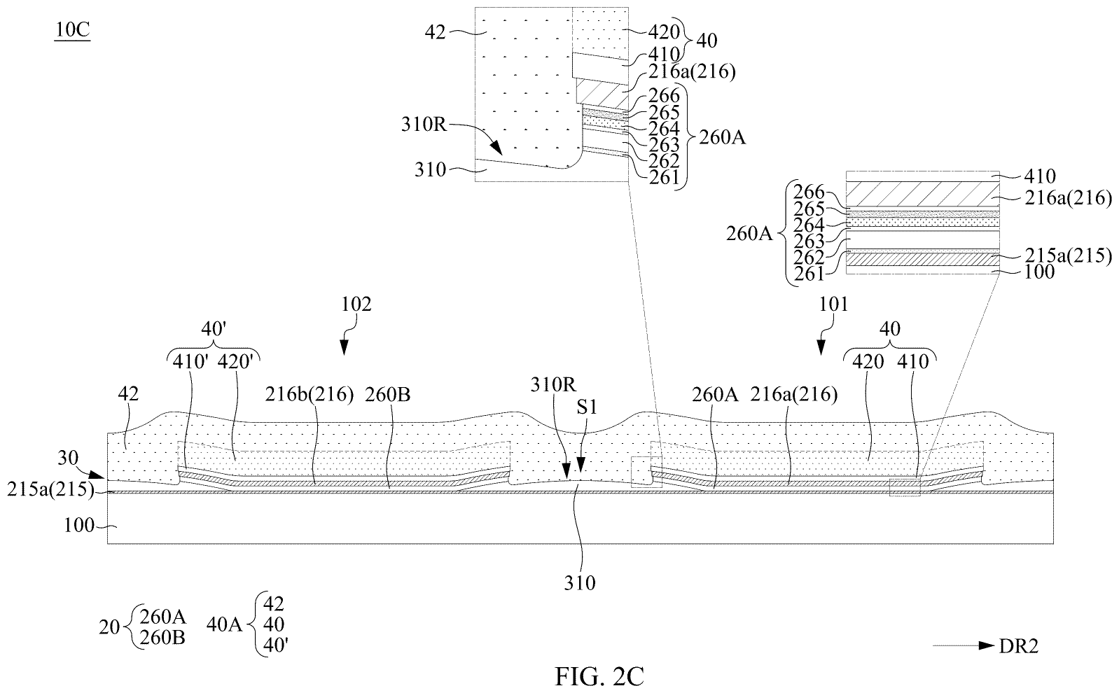

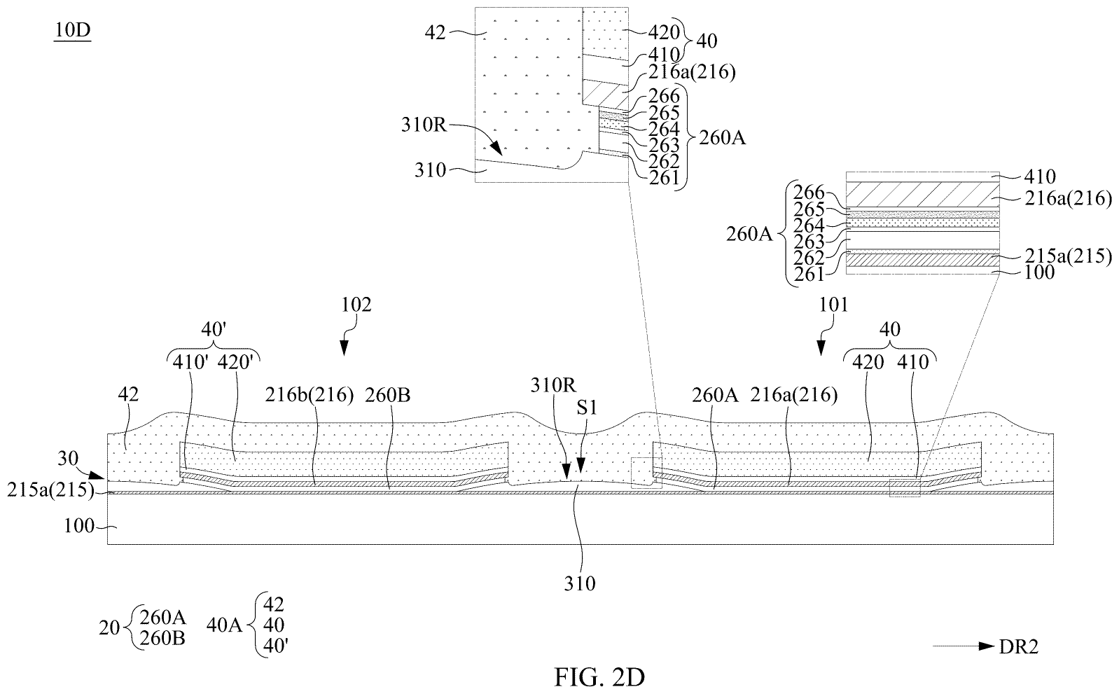

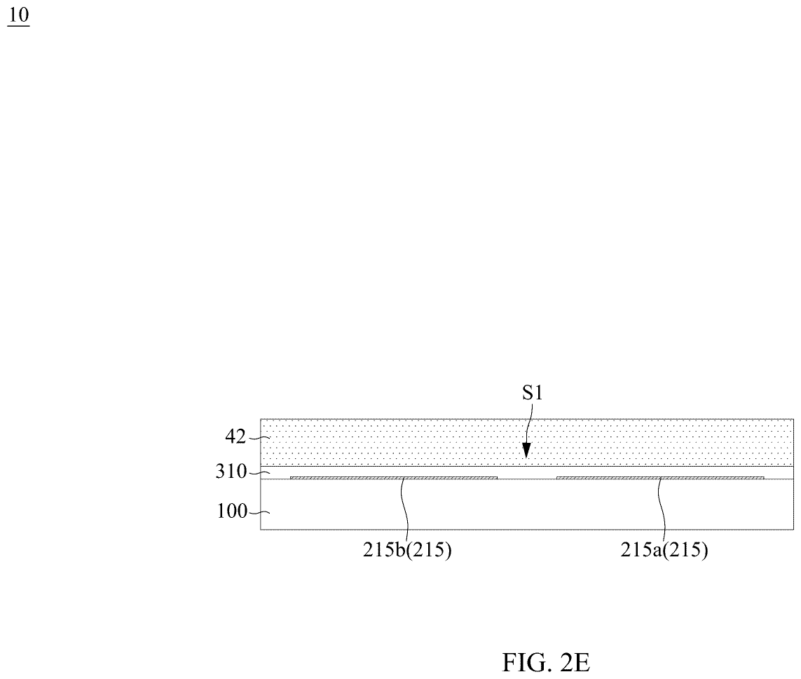

FIG. 2A shows a section diagram of an organic light emitting element 10A. In some embodiments, FIG. 2A is a section diagram along the line A-A′ in FIG. 1. In some embodiments, FIG. 2A shows a section diagram along the line A-A′ in FIG. 1 as an example, and only a light emitting region is illustrated. The spacer structure 30 includes a plurality of protrusions 310 to define a light emitting pixel pattern. A recess is located between two adjacent protrusions 310 and provides a space for accommodating light emitting pixels. When viewing the section diagram shown in FIG. 2A, a person skilled in the art would be able to understand that the protrusions 310 are depicted in a disconnected manner. However, when viewing the schematic top view of FIG. 1, the protrusions 310 can be connected to one another by other parts of the spacer structure 30.

As shown in FIG. 2A, in some embodiments, the organic light emitting element 10 is, for example, a light emitting element including an organic light emitting diode (OLED). In some embodiments, the organic light emitting element 10 includes a plurality of organic light emitting units (or referred to as light emitting pixels), for example, including at least an organic light emitting unit 101 (or referred to as a first organic light emitting unit) and an organic light emitting unit 102 (or referred to as a second organic light emitting unit). In some embodiments, the organic light emitting units 101 and 102 are between the protrusions 310 and above the substrate 100. The organic light emitting units 101 and 102 may emit light having the same wavelength or light having different wavelengths.

In some embodiments, the organic light emitting element 10 includes a substrate 100, an electrode 215a (or referred to as a first bottom electrode), an electrode 216a (or referred to as a first top electrode), an electrode 216b (or referred to as a second top electrode), a light emitting layer 20, a spacer structure 30 (or referred to as a pixel defined layer) and a cover structure 40A.

In some embodiments, the substrate 100 may include a transistor array, which is configured to correspond to light emitting pixels in the light emitting layer 20. The substrate 100 may include a plurality of capacitors. In some embodiments, more than one transistor is configured with one capacitor and one light emitting pixel to form a circuit. In some embodiments, the substrate 100 may include glass.

In some embodiments, the light emitting layer 20 is located over the electrode 215. In some embodiments, the light emitting layer 20 includes an organic light emitting layer 260A (or referred to as a first organic light emitting layer), and an organic light emitting layer 260B (or referred to as a second organic light emitting layer).

In some embodiments, the electrode 215a is located over the substrate 100. In some embodiments, the electrode 215a is an anode. In some embodiments, the electrode 215a includes a metal material, for example, Ag, Al, Mg, Au, AlCu alloy or AgMo alloy. In some embodiments, the electrode 215a includes indium tin oxide (ITO), indium zinc oxide (IZO) or other appropriate materials. In some embodiments, the organic light emitting layer 260A and the organic light emitting layer 260B are located over the electrode 215a.

In some embodiments, the electrode 216a and the electrode 216b are located over the light emitting layer 20. In some embodiments, the electrode 216a is located over the organic light emitting layer 260A, and the electrode 216b is located over the organic light emitting layer 260B. In some embodiments, the electrode 216a is in contact with the organic light emitting layer 260A, and the electrode 216b is in contact with the organic light emitting layer 260B. In some embodiments, the electrodes 216a and 216b may be further located over the spacer structure 30 (or the pixel defined layer). In some embodiments, the electrodes 216a and 216b are separated by a space S1. In some embodiments, the electrodes 216a and 216b include a metal material, for example, Ag, Al, Mg, Au, AlCu alloy or AgMo alloy. In some embodiments, the electrodes 216a and 216b include ITO, IZO or other appropriate materials.

In some embodiments, the organic light emitting layer 260A is located between the electrode 215a and the electrode 216a, and the organic light emitting layer 260B is located between the electrode 215a and the electrode 216b. In some embodiments, the organic light emitting layer 260A and the organic light emitting layer 260B are separated by the spacer S1. In some embodiments, the organic light emitting layers 260A and 260B emit light in the same color or different colors. In some embodiments, a luminescence wavelength of the organic light emitting layer 260A is the same as a luminescence wavelength of the organic light emitting layer 260B. In some embodiments, the luminescence wavelength of the organic light emitting layer 260B is greater than the luminescence wavelength of the organic light emitting layer 260A.

In some embodiments, the organic light emitting layers 260A and 260B include an organic material, which may be placed in any of the organic light emitting layers 260A and 260B according to different implementation forms. In some embodiments, the organic material has an absorption rate of greater than or equal to 50% for a specific wavelength. In some embodiments, the organic material has an absorption rate of greater than or equal to 60% for a specific wavelength. In some embodiments, the organic material has an absorption rate of greater than or equal to 70% for a specific wavelength. In some embodiments, the organic material has an absorption rate of greater than or equal to 80% for a specific wavelength. In some embodiments, the organic material has an absorption rate of greater than or equal to 90% for a specific wavelength. In some embodiments, the organic material has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, In some embodiments, each of the organic light emitting layers 260A and 260B includes multiple organic material layers, for example, a hole injection layer (HIL) 261, a hole transport layer (HTL) 262, an electron barrier layer (EBL) 263, an organic emission layer (EML) 264, an electron transport layer (ETL) 265 and an electron injection layer (EIL) 266.

In some embodiments, the organic light emitting unit 101 includes the electrode 215a (or referred to as the first bottom electrode), the organic light emitting layer 260A, and the electrode 216a (or referred to as the first top electrode). In some embodiments, the organic light emitting unit 102 includes the electrode 215a (or referred to as the first bottom electrode), the organic light emitting layer 260B, and the electrode 216b (or referred to as the second top electrode).

In some embodiments, the spacer structure 30 is located on the substrate 100 and partially covers the electrode 215a. In some embodiments, the spacer structure 30 is located between the organic light emitting layers 260A and 260B. In some embodiments, the spacer structure 30 is located between the electrodes 216a and the electrode 216b. In some embodiments, a pattern of the spacer structure 30 is designed according to a pixel layout. In some embodiments, the spacer structure 30 serves as a pixel defined layer (PDL). In some embodiments, the spacer structure 30 may include protrusions 310. In some embodiments, the protrusions 310 define a pixel region. In some embodiments, the protrusions 310 are located over the substrate 100 and partially cover the electrode 215a. In some embodiments, thickness of the spacer structure 30 is greater than or equal to 0.5 μm, for example, 0.5 μm to 2 μm, or 0.6 μm to 1 μm.

In some embodiments, the spacer structure 30 (or the pixel defined layer) includes an organic insulating material. In some embodiments, the protrusion 310 may include or is referred to as an insulation protrusion. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a black material, which has an absorption rate of more than 90%, 95%, 99%, 99.5% 99.9% for visible light.

In some embodiments, the spacer structure 30 has an absorption rate of greater than or equal to 50% for a specific wavelength. In some embodiments, the spacer structure 30 has an absorption rate of greater than or equal to 60% for a specific wavelength. In some embodiments, the spacer structure 30 has an absorption rate of greater than or equal to 70% for a specific wavelength. In some embodiments, the spacer structure 30 has an absorption rate of greater than or equal to 80% for a specific wavelength. In some embodiments, the spacer structure 30 has an absorption rate of greater than or equal to 90% for a specific wavelength. In some embodiments, the spacer structure 30 has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the cover structure 40A includes cover layers 40 and 40′ and an encapsulation layer 42 (or referred to as a top encapsulation layer). In some embodiments, the cover layer 40 is located over the electrode 216a, the cover layer 40′ is located over the electrode 216b, and the cover layer 40 and the cover layer 40′ are separated from each other. In some embodiments, the cover layer 40 and the cover layer 40′ are separated by the space S1. In some embodiments, thickness of the cover layer 40 is greater than thickness of the organic light emitting layer 260A. In some embodiments, the thickness of the cover layer 40 is more than 5 times the thickness of the organic light emitting layer 260A, for example, 5 to 20 times. In some embodiments, thickness of the cover layer 40′ is greater than a thickness of the organic light emitting layer 260B. In some embodiments, the thickness of the cover layer 40′ is more than 5 times the thickness of the organic light emitting layer 260B, for example, 5 to 20 times. In some embodiments, the thickness of the cover layer 40 is greater than thickness of the electrode 216a. In some embodiments, the thickness of the cover layer 40 is more than 5 times the thickness of the electrode 216a, for example, 5 to 30 times. In some embodiments, the thickness of the cover layer 40′ is greater than thickness of the electrode 216b. In some embodiments, the thickness of the cover layer 40′ is more than 5 times the thickness of the electrode 216b, for example, 5 to 30 times.

In some embodiments, the cover layer 40 includes a capping layer 410 and an encapsulation layer 420, and the cover layer 40′ includes a capping layer 410′ and an encapsulation layer 420′. In some embodiments, thickness of the encapsulation layer 420 is greater than thickness of the capping layer 410. In some embodiments, the thickness of the encapsulation layer 420 is more than 5 times the thickness of the capping layer 410, for example, 5 to 50 times. In some embodiments, thickness of the encapsulation layer 420′ is greater than thickness of the capping layer 410′. In some embodiments, the thickness of the encapsulation layer 420′ is more than 5 times the thickness of the capping layer 410′, for example, 5 to 50 times.

In some embodiments, the capping layer 410 is arranged over the electrode 216a, and is substantially conformal with a non-flat upper surface of the electrode 216a. In some embodiments, the capping layer 410′ is arranged over the electrode 216b, and is substantially conformal with a non-flat upper surface of the electrode 216b. The capping layers 410 and 410′ may include a dielectric material or an inorganic insulating material, for example, SiO₂. In some embodiments, the capping layers 410 and 410′ may include a hole transport layer material to extract light lost inside the organic light emitting element so as to improve light emitting efficiency. The capping layers 410 and 410′ may also be referred to as light extraction layers.

In some embodiments, the encapsulation layer 420 is arranged over the capping layer 410, and is substantially conformal with a non-flat upper surface of the capping layer 410. In some embodiments, the encapsulation layer 420′ is arranged over the capping layer 410′, and is substantially conformal with a non-flat upper surface of the capping layer 410′. In some embodiments, the encapsulation layer 420 is substantially conformal with a non-flat upper surface of the capping layer 410, and has a recess corresponding to the organic light emitting layer 260A. In some embodiments, the encapsulation layer 420′ is substantially conformal with a non-flat upper surface of the capping layer 410′, and has a recess corresponding to the organic light emitting layer 260B. The encapsulation layers 420 and 420′ may include an oxide, for example, SiO₂. The encapsulation layers 420 and 420′ may include a polymer organic material, for example, an epoxy-based material.

In some embodiments, the encapsulation layer 42 continuously extends over the cover layer 40 and the cover layer 40′. In some embodiments, the encapsulation layer 42 is arranged over the cover layer 40 and the cover layer 40′, and is substantially conformal with a non-flat upper surface formed by the capping layer 40, the capping layer 40′ and the spacer structure 30 (or the pixel defined layer). In some embodiments, the organic light emitting layer 260A and the organic light emitting layer 260B are in contact with the encapsulation layer 42 and are separated from each other by the encapsulation layer 42. In some embodiments, the cover layer 40 and the cover layer 40′ are in contact with the encapsulation layer 42 and are separated from each other by the encapsulation layer 42. In some embodiments, the capping layer 410 and the capping layer 410′ are in contact with the encapsulation layer 42 and are separated from each other by the encapsulation layer 42. In some embodiments, the encapsulation layer 420 and the encapsulation layer 420′ are in contact with the encapsulation layer 42 and are separated from each other by the encapsulation layer 42. In some embodiments, the electrode 216a and the electrode 216b are in contact with the encapsulation layer 42 and are separated from each other by the encapsulation layer 42.

In some embodiments, thickness of the encapsulation layer 42 is greater than the thickness of the organic light emitting layer 260A. In some embodiments, the thickness of the encapsulation layer 42 is more than 5 times the thickness of the organic light emitting layer 260A, for example, 5 to 20 times. In some embodiments, the thickness of the encapsulation layer 42 is greater than the thickness of the organic light emitting layer 260B. In some embodiments, the thickness of the encapsulation layer 42 is more than 5 times the thickness of the organic light emitting layer 260B, for example, 5 to 20 times. In some embodiments, the thickness of the encapsulation layer 42 is greater than thickness of the electrode 216a. In some embodiments, the thickness of the encapsulation layer 42 is more than 5 times the thickness of the electrode 216a, for example, 5 to 20 times. In some embodiments, the thickness of the encapsulation layer 42 is greater than thickness of the electrode 216b. In some embodiments, the thickness of the encapsulation layer 42′ is more than 5 times the thickness of the electrode 216b, for example, 5 to 30 times.

In some embodiments, a partial surface of the spacer structure 30 (or the pixel defined layer), a sidewall of the organic light emitting layer 260A, a sidewall of the organic light emitting layer 260B, an end of the electrode 216a, an end of the electrode 216b, a sidewall of the capping layer 410 and a sidewall of the capping layer 410′ define the space S1. In some embodiments, a portion of the protrusion 310 is exposed from the space S1. In some embodiments, the organic light emitting layer 260A and the organic light emitting layer 260B are separated from each other by the space S1. In some embodiments, the electrode 216a and the electrode 216b are separated from each other by the space S1. In some embodiments, the cover layer 40 and the cover layer 40′ are separated from each other by the space S1. In some embodiments, the encapsulation layer 42 is located in or fills the space S1. In some embodiments, the organic light emitting layer 260A and the organic light emitting layer 260B are separated from each other by the encapsulation layer 42 in the space S1. In some embodiments, the electrode 216a and the electrode 216b are separated from each other by the encapsulation layer 42 in the space S1. In some embodiments, the cover layer 40 and the cover layer 40′ are separated from each other by the encapsulation layer 42 in the space S1. In some embodiments, a portion of the encapsulation layer 42 continuously extends to the space S1 between the cover layer 40 and the cover layer 40′ and is contact with the protrusion 310.

According to some embodiments of the present disclosure, the multiple electrodes 216 are separated from one another by the space S1, and are orthogonal to the multiple electrodes 215 at multiple light emitting units (or light emitting pixels). Thus, lighting up at any single point of multiple light emitting units (or light emitting pixels) can be individually controlled, so that the organic light emitting element 10 is able to display multiple types of predetermined light emitting patterns. For example, when the organic light emitting element 10A is applied to a collimator apparatus, multi-point display images may be presented according to designs of ballistics.

Moreover, according to some embodiments of the present disclosure, the multiple electrodes 216 are physically separated from one another by the encapsulation layer 42. Thus, in addition to effectively electrically insulating the multiple electrodes 216 from one another, the electrodes 216 are also protected by an encapsulation material of the encapsulation layer 42, hence preventing the electrodes 216 from damage of the external environment and further improving the reliability and process yield rate of the organic light emitting element 10A.

According to some embodiments of the present disclosure, the organic light emitting layer 260A and the organic light emitting layer 260B are similarly separated by the encapsulation layer 42. As such, additional patterned photolithography and etching processes for patterning an organic light emitting material and forming multiple separated organic light emitting layers are not needed. Thus, processes of the organic light emitting layers can be simplified.

FIG. 2B shows a section diagram of an organic light emitting element 10B. In some embodiments, FIG. 2B shows a section diagram of the organic light emitting unit 10 in FIG. 1. In some embodiments, FIG. 2B is a section diagram along the line A-A′ in FIG. 1. In some embodiments, FIG. 2B shows a section diagram along the line A-A′ in FIG. 1 as an example, and only a light emitting region is illustrated. The structure in FIG. 2B is similar to the structure in FIG. 2A, and differences thereof are described below.

In some embodiments, the protrusion 310 has a trench 310R, and the trench 310R is in communication with the space S1. In some embodiments, the encapsulation layer 42 continuously extends over the cover layer 40 and the cover layer 40′, and extends into the space S1 and the trench 310R. In some embodiments, a sidewall of the trench 310R is recessed relative to the sidewall of the organic light emitting layer 260A.

In some embodiments, the sidewall of the organic light emitting layer 260A is recessed relative to the sidewall of the electrode 216a, and the sidewall of the organic light emitting layer 260B is recessed relative to a sidewall of the electrode 216b. In some embodiments, the sidewall of the organic light emitting layer 260A is recessed relative to the sidewall of the cover layer 40, and the sidewall of the organic light emitting layer 260B is recessed relative to the sidewall of the cover layer 40′. In some embodiments, the sidewall of the capping layer 410 is recessed relative to the sidewall of the encapsulation layer 420, and the sidewall of the capping layer 410 is recessed relative to the sidewall of the electrode 216a.

In some embodiments, the encapsulation layer 42 extends into the space S1. In some embodiments, the encapsulation layer 42 fills a recess formed by the sidewall of the trench 310R and a lower surface of the organic light emitting layer 260A. In some embodiments, the encapsulation layer 42 fills a recess formed by a lower surface of the encapsulation layer 420, an upper surface of the electrode 216a and the sidewall of the capping layer 410.

According to some embodiments of the present disclosure, the multiple electrodes 216 are physically separated from one another by the encapsulation layer 42. Moreover, the encapsulation layer 42 furthers fills multiple recesses. Thus, in addition to effectively electrically insulating the multiple electrodes 216 from one another to effectively prevent the problem of lighting failure at one single point caused by short-circuitry between adjacent light emitting units (or light emitting pixels), a bonding force between the encapsulation layer 42 and a stacked layer structure of the organic light emitting units is increased by fitting between the encapsulation layer 42 and the recesses to further improve the reliability and process yield rate of the organic light emitting element 10A.

FIG. 2C shows a section diagram of an organic light emitting element 10C. In some embodiments, FIG. 2C shows a section diagram of the organic light emitting unit 10 in FIG. 1. In some embodiments, FIG. 2C is a section diagram along the line A-A′ in FIG. 1. In some embodiments, FIG. 2C shows a section diagram along the line A-A′ in FIG. 1 as an example, and only a light emitting region is illustrated. The structure in FIG. 2C is similar to the structure in FIG. 2A, and differences thereof are described below.

In some embodiments, the sidewall of the organic light emitting layer 260A is recessed relative to the sidewall of the electrode 216a, and the sidewall of the organic light emitting layer 260B is recessed relative to the sidewall of the electrode 216b. In some embodiments, the sidewall of the electrode 216a is recessed relative to the sidewall of the cover layer 40, and the sidewall of the electrode 216b is recessed relative to the sidewall of the cover layer 40′. In some embodiments, the sidewall of the electrode 216a is recessed relative to the sidewall of the capping layer 410, and the sidewall of the electrode 216b is recessed relative to the sidewall of the capping layer 410′.

In some embodiments, the encapsulation layer 420 and the encapsulation layer 42 include or are formed of the same material, and thus the encapsulation layer 420 and the encapsulation layer 42 do not have any visible interface in between. In some embodiments, the encapsulation layer 420′ and the encapsulation layer 42 include or are formed of the same material, and thus the encapsulation layer 420′ and the encapsulation layer 42 does not have any observable interface in between.

According to some embodiments of the present disclosure, the multiple electrodes 216 are physically separated from one another by the encapsulation layer 42. Moreover, the encapsulation layer 42 furthers fills multiple recesses. Thus, in addition to effectively electrically insulating the multiple electrodes 216 from one another to effectively prevent the problem of lighting failure at one single point caused by short-circuitry between adjacent light emitting units (or light emitting pixels), a bonding force between the encapsulation layer 42 and a stacked layer structure of the organic light emitting units is increased by fitting between the encapsulation layer 42 and the recesses to further improve the reliability and process yield rate of the organic light emitting element 10C.

Moreover, according to some embodiments of the present disclosure, the encapsulation layers 420 and 420′ and the encapsulation layer 42 include or are formed of the same material, and thus bonding strengths between the encapsulation layers 420 and 420′ and the encapsulation layer 42 are further increased to thereby improve the reliability and process yield rate of the organic light emitting element 10C.

FIG. 2D shows a section diagram of an organic light emitting element 10D. In some embodiments, FIG. 2D shows a section diagram of the organic light emitting unit 10 in FIG. 1. In some embodiments, FIG. 2D is a section diagram along the line A-A′ in FIG. 1. In some embodiments, FIG. 2D shows a section diagram along the line A-A′ in FIG. 1 as an example, and only a light emitting region is illustrated. The structure in FIG. 2D is similar to the structure in FIG. 2A, and differences thereof are described below.

In some embodiments, the sidewall of the organic light emitting layer 260A is recessed relative to the sidewall of the trench 310R, and the sidewall of the organic light emitting layer 260B is recessed relative to the sidewall of the trench 310R. In some embodiments, the sidewall of the organic light emitting layer 260A is recessed relative to the sidewall of the electrode 216a, and the sidewall of the organic light emitting layer 260B is recessed relative to the sidewall of the electrode 216b.

According to some embodiments of the present disclosure, the multiple electrodes 216 are physically separated from one another by the encapsulation layer 42. Moreover, the encapsulation layer 42 furthers fills multiple recesses. Thus, in addition to effectively electrically insulating the multiple electrodes 216 from one another to effectively prevent the problem of lighting failure at one single point caused by short-circuitry between adjacent light emitting units (or light emitting pixels), a bonding force between the encapsulation layer42 and a stacked layer structure of the organic light emitting units is increased by fitting between the encapsulation layer 42 and the recesses to further improve the reliability and process yield rate of the organic light emitting element 10D.

FIG. 2E shows a section diagram of the organic light emitting element 10. In some embodiments, FIG. 2E is a section diagram along the line E-E′ in FIG. 1. In some embodiments, FIG. 2E shows a section diagram along the line E-E′ in FIG. 1 and only a light emitting region is illustrated.

In some embodiments, the electrodes 215a and 215b are separated from each other by the spacer structure 30 (or the pixel defined layer). In some embodiments, the electrodes 215a and 215b are separated from each other by the protrusion 310 (or the insulation protrusion). In some embodiments, the encapsulation layer 42 is located over the protrusion 310 and is in contact with the protrusion 310.

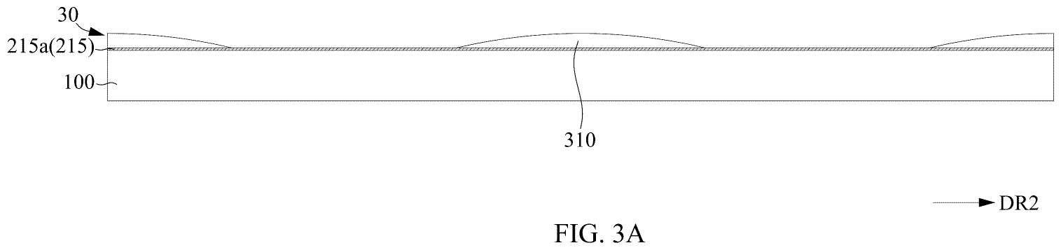

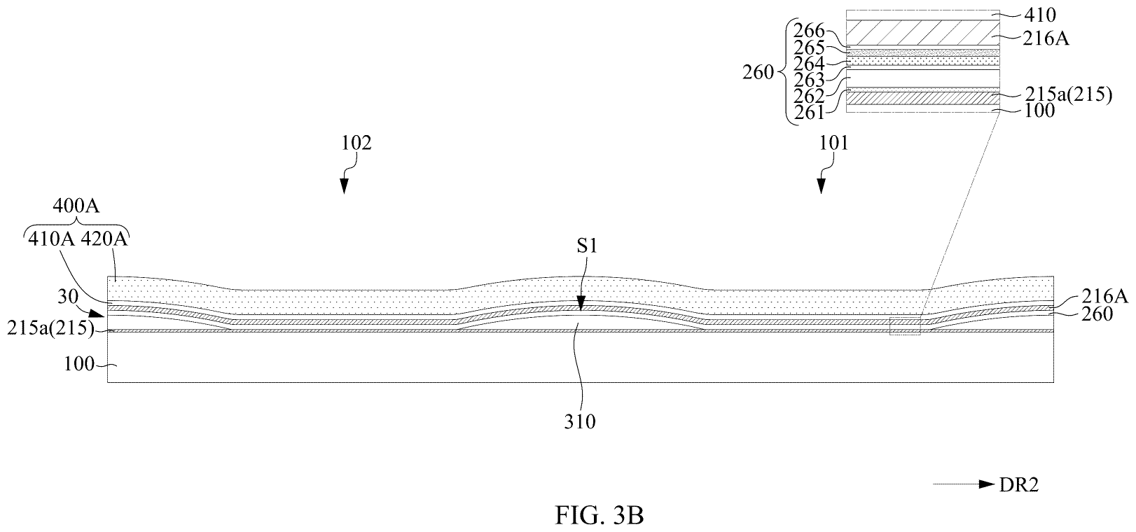

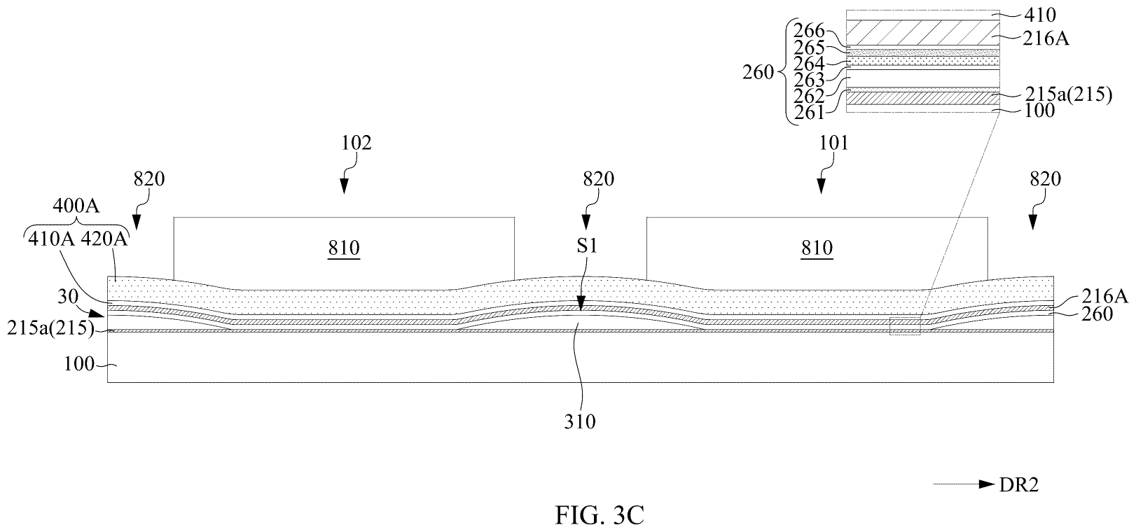

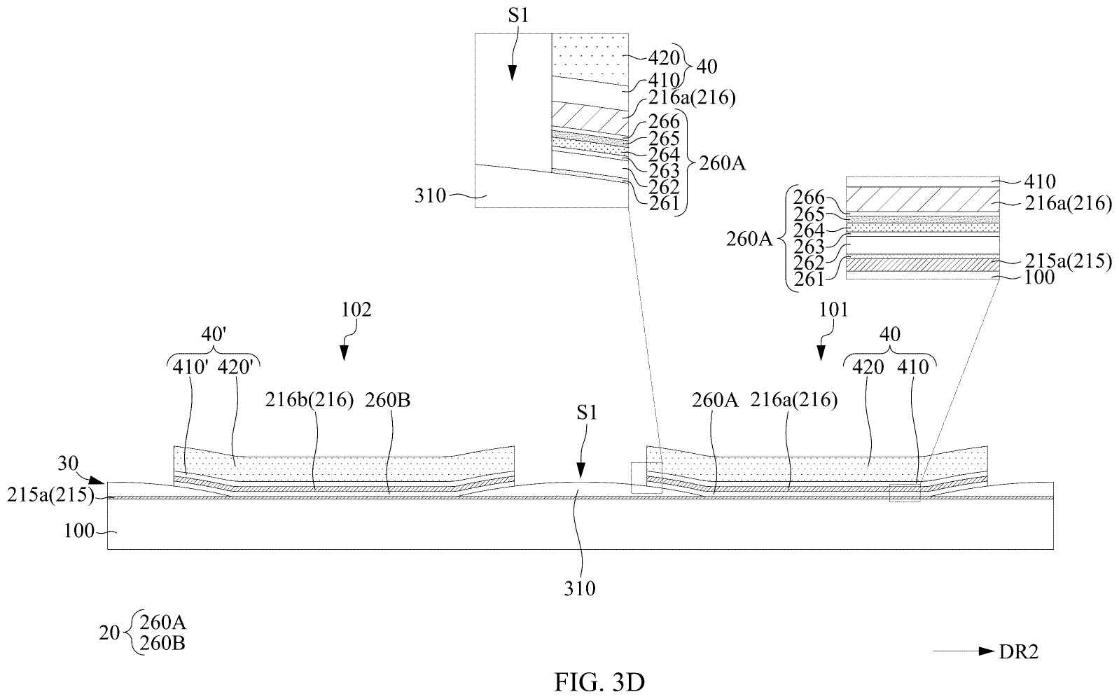

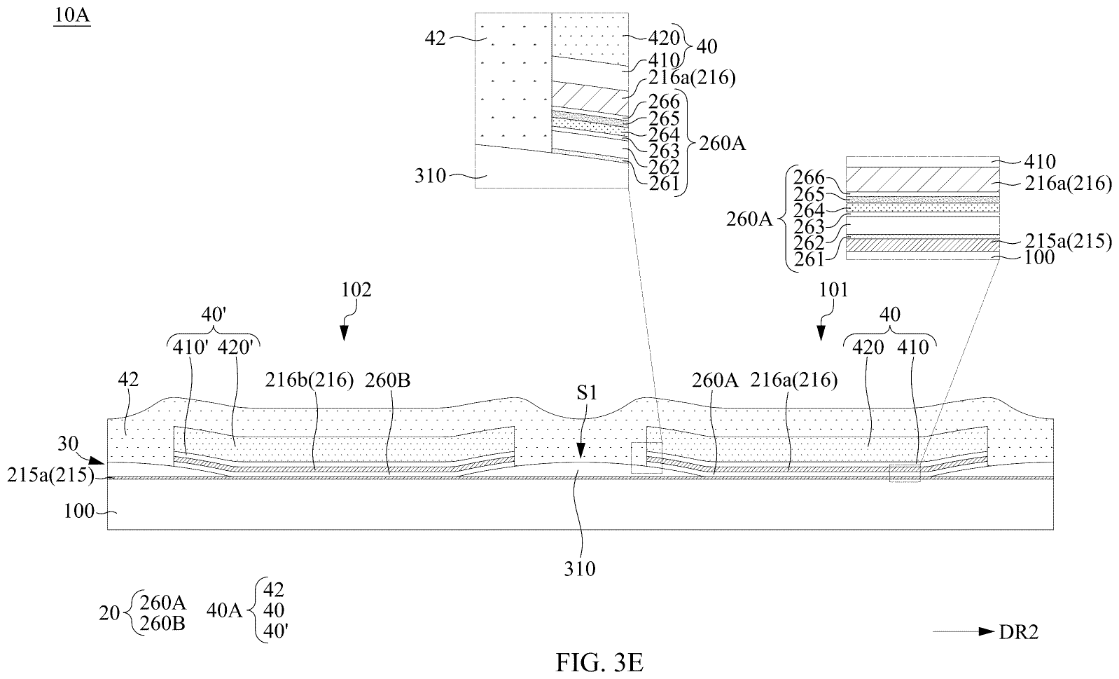

FIG. 4A to FIG. 3E depict a manufacturing method of an organic light emitting element 10A according to some embodiments.

As shown in FIG. 3A, in some embodiments, a substrate 100 is provided, an electrode 215a is arranged over the substrate 100, and a plurality of protrusions 310 (or a spacer structure 30) are formed over the electrode 215a. In some embodiments, multiple electrodes 215 (referring to FIG. 1) are arranged over the substrate 100, and the spacer structure 30 is formed over the multiple electrodes 215. The multiple electrodes 215 may be manufactured by photolithography and etching processes. In some embodiments, the protrusions 310 (or insulation protrusions) are located over the substrate 100 and partially cover the electrode 215.

Next, as shown in FIG. 3B, in some embodiments, an organic light emitting layer structure 260, an electrode material layer 216A and a cover material layer 400A are formed over the spacer structure 30 and the electrode 215a.

In some embodiments, an organic light emitting material layer 260 as a whole surface is formed over the spacer structure 30 and the electrode 215a by means of evaporation. In some embodiments, the electrode material layer 216A as a whole surface is formed over the organic light emitting material layer 260 by means of evaporation. Up to this point, the organic light emitting units 101 and 102 are formed. Next, in some embodiments, the cover material layer 400A as a whole surface is formed over the electrode material layer 216A by means of evaporation. In some embodiments, a capping material layer 410A as a whole surface is formed over the electrode material layer 216A by means of evaporation, and an encapsulation material layer 420A as a whole surface is formed over the capping material layer 410A by means of evaporation.

In some embodiment, a hole injection layer (HIL) 261 as a whole surface is formed over surfaces of spacer structure 30 and the electrode 215a, a hole transport layer (HTL) 262 as a whole surface is formed over the hole injection layer (HIL) 261, an electron barrier layer (EBL) 263 as a whole surface is formed over the hole transport layer (HTL) 262, an organic emission layer (EML) 264 as a whole surface is formed over the electron barrier layer (EBL) 263, an electron transport layer (ETL) 265 as a whole surface is formed over the organic emission layer (EML) 264, and an electron injection layer (EIL) 266 as a whole surface is formed over the electron transport layer (ETL) 265. In some embodiments, the hole injection layer (HIL) 261, the hole transport layer (HTL) 262, the electron barrier layer (EBL) 263, the organic emission layer (EML) 264, the electron transport layer (ETL) 265 and the electron injection layer (EIL) 266 are formed by means of evaporation.

As shown in FIG. 3C, in some embodiments, a patterned photosensitive layer 810 is arranged over the cover material layer 400A. In some embodiments, the photosensitive layer is formed by means of coating. Next, in some embodiments, the photosensitive layer is patterned by a lithography process to form the patterned photosensitive layer 810, such that a portion of the cover material layer 400A is exposed from a groove 820.

As shown in FIG. 3D, in some embodiments, a separation step is performed to separate the cover material layer 400A into the cover layer 40 and the cover layer 40′ separated from each other. In some embodiments, the electrode material layer 216 is separated into the electrode 216a and the electrode 216b separated from each other by the separation step. In some embodiments, the organic light emitting layer structure 260 is separated into the organic light emitting layer 260A and the organic light emitting layer 260B separated from each other by the separation step.

In some embodiments, the separation step is performed by one or multiple rounds of dry etching process. In some embodiments, the organic light emitting layer structure 260, a portion of the electrode material layer 216 and a portion of the cover material layer 400A are removed by one round or multiple rounds of dry etching process to form the space S1. In some embodiments, an upper surface of a portion of the protrusion 310 (or the insulation protrusion) is exposed from the space S1. In some embodiments, the organic light emitting layer 260A and the organic light emitting layer 260B are separated from each other by the space S1. In some embodiments, the electrode 216a and the electrode 216b are separated from each other by the space S1. In some embodiments, the cover layer 40 and the cover layer 40′ are separated from each other by the space S1.

As shown in FIG. 3E, in some embodiments, the encapsulation layer 42 is formed to continuously extend over the cover layer 40 and the cover layer 40′. In some embodiments, the encapsulation layer 42 is formed by means of evaporation. In some embodiments, the encapsulation layer 42 is formed in the space S1 and is in contact with the sidewall of the organic light emitting layer 260A, the sidewall of the organic light emitting layer 260B, the sidewall of the electrode 216a, the sidewall of the electrode 216b, the sidewall of the cover layer 40 and the sidewall of the cover layer 40′. Up to this point, the organic light emitting element 10A shown in FIG. 2A is formed.

In some embodiments, referring to FIG. 2B and FIG. 3D, the separation step further removes a portion of the protrusion 310 (or the insulation protrusion). In some embodiments, a portion of the protrusion 310 (or the insulation protrusion) is removed by an etching process to form the trench 310R. In some embodiments, a portion of the organic light emitting structure 260 and a portion of the protrusion 310 are removed by different etching processes, such that the sidewall of the trench 310R has an undercut structure. In some embodiments, the etching process for removing a portion of the electrode material layer 216 or the etching process for removing a portion of the cover material layer 400A also removes a portion of the protrusion 310 (or the insulation protrusion), such that the sidewall of the trench 310R has an undercut structure.

In some embodiments, referring to FIG. 2B and FIG. 3D, the patterned photosensitive layer 810 is removed by means of a wet etching step. In some embodiments, the wet etching step for removing the patterned photosensitive layer 810 further removes a portion of the organic light emitting layer 260A and a portion of the organic light emitting layer 260B, such that the sidewall of the organic light emitting layer 260A is recessed relative to the sidewall of the cover layer 40, and the sidewall of the organic light emitting layer 260B is recessed relative to the sidewall of the cover layer 40′. Next, referring to the step in FIG. 3E, the encapsulation layer 42 is formed, and the organic light emitting element 10B shown in FIG. 2B is formed.

In some embodiments, referring to FIG. 2C and FIG. 3D, a portion of the organic light emitting layer structure 260 and a portion of the protrusion 310 (or the insulation protrusion) are removed by one single round of etching process to form the trench 310R, such that the sidewall of the trench 310R is substantially flush with the sidewalls of the organic light emitting layers 260A and 260B. In some embodiments, a portion of the organic light emitting layer structure 260 and a portion of the protrusion 310 (or the insulation protrusion) are removed by one single round of dry etching process to form the trench 310R. Next, referring to the step in FIG. 3E, the encapsulation layer 42 is formed, and the organic light emitting element 10C shown in FIG. 2C is formed.

In some embodiments, referring to FIG. 2B and FIG. 3D, the patterned photosensitive layer 810 is removed by means of a wet etching step. In some embodiments, the wet etching step for removing the patterned photosensitive layer 810 further removes a portion of the organic light emitting layer 260A and a portion of the organic light emitting layer 260B, such that the sidewall of the organic light emitting layer 260A and the sidewall of the organic light emitting layer 260B are recessed relative to the sidewall of the trench 310R. Next, referring to the step in FIG. 3E, the encapsulation layer 42 is formed, and the organic light emitting element 10D shown in FIG. 2D is formed.

The features of some embodiments are given in brief in the description above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made by a person skilled in the art without departing from the spirit and scope of the present disclosure.

What is claimed is:

1. An organic light emitting element, comprising:
a substrate;
a first bottom electrode over the substrate;
a first organic light emitting layer and a second organic light emitting layer over the first bottom electrode;
a first top electrode and a second top electrode respectively over the first organic light emitting layer and the second organic light emitting layer, wherein an extension direction of the first top electrode and an extension direction of the second top electrode are substantially perpendicular to an extension direction of the first bottom electrode; and
a first cover layer and a second cover layer respectively over the first top electrode and the second top electrode, wherein the first cover layer and the second cover layer are separated from each other.

2. The organic light emitting element according to claim 1, further comprising:
a top encapsulation layer continuously extending over the first cover layer and the second cover layer.

3. The organic light emitting element according to claim 2, further comprising:
an insulation protrusion over the substrate and partially covering the first bottom electrode, wherein a portion of the top encapsulation layer extends between the first cover layer and the second cover layer and is in contact with the insulation protrusion.

4. The organic light emitting element according to claim 2, wherein the first organic light emitting layer and the second organic light emitting layer are in contact with the top encapsulation layer and are separated from each other by the top encapsulation layer.

5. The organic light emitting element according to claim 2, wherein the first cover layer and the second cover layer are separated from each other by the top encapsulation layer.

6. The organic light emitting element according to claim 5, wherein the first cover layer comprises a first capping layer and a first encapsulation layer over the first capping layer, the second cover layer comprises a second capping layer and a second encapsulation layer over the second capping layer, and the first encapsulation layer and the second encapsulation layer are in contact with the top encapsulation layer and are separated from each other by the top encapsulation layer.

7. The organic light emitting element according to claim 2, wherein the first top electrode and the second top electrode are in contact with the top encapsulation layer and are separated from each other by the top encapsulation layer.

8. The organic light emitting element according to claim 1, further comprising:
an insulation protrusion over the substrate and partially covering the first bottom electrode, wherein the first cover layer and the second cover layer are separated from each other by a space, and a portion of the insulation protrusion is exposed from the space.

9. The organic light emitting element according to claim 8, wherein the insulation protrusion comprises a trench, and the trench is connected to the space.

10. The organic light emitting element according to claim 9, further comprising:
a top encapsulation layer continuously extending over the first cover layer and the second cover layer and extending into the space and the trench.

11. The organic light emitting element according to claim 9, wherein a sidewall of the trench is recessed relative to a sidewall of the first organic light emitting layer.

12. The organic light emitting element according to claim 9, wherein a sidewall of the first organic light emitting layer is recessed relative to a sidewall of the trench.

13. The organic light emitting element according to claim 1, wherein a sidewall of the first organic light emitting layer is recessed relative to a sidewall of the first cover layer.

14. The organic light emitting element according to claim 1, wherein a sidewall of the first organic light emitting layer is recessed relative to a sidewall of the first top electrode.

15. A manufacturing method of an organic light emitting element, comprising:
providing a substrate;
arranging a first bottom electrode over the substrate;
forming an organic light emitting layer structure over the first bottom electrode;
forming a top electrode material layer over the organic light emitting layer structure;
forming a cover material layer over the top electrode material layer; and
performing a separation step to separate the cover material layer into a first cover layer and a second cover layer separated from each other.

16. The manufacturing method according to claim 15, further comprising:
forming a top encapsulation layer as continuously extending over the first cover layer and the second cover layer.

17. The manufacturing method according to claim 16, further comprising:
before forming the top encapsulation layer, performing a separation step to separate the top electrode material layer into a first top electrode and a second top electrode separated from each other.

18. The manufacturing method according to claim 16, further comprising:
before forming the top encapsulation layer, performing a separation step to separate the organic light emitting layer structure into a first organic light emitting layer and a second organic light emitting layer separated from each other.

19. The manufacturing method according to claim 18, further comprising:
before performing the separation step, arranging a patterned photosensitive layer over the cover material layer; and
after performing the separation step, removing the patterned photosensitive layer by a wet etching step, wherein the wet etching step further removes a portion of the first organic light emitting layer and a portion of the second organic light emitting layer, such that a sidewall of the first organic light emitting layer and a sidewall of the second organic light emitting layer are recessed relative to a sidewall of the first cover layer.

20. The manufacturing method according to claim 16, further comprising:
forming an insulation protrusion over the substrate to partially cover the first bottom electrode, wherein the separation step further removes a portion of the insulation protrusion.
